(19) United States
(12) Patent Application Publication
(10) Pub. No.: US 2026/0197940 A1
(43) Pub. Date: Jul. 9, 2026

(54) WIRING BOARD AND WIRING BOARD MANUFACTURING METHOD

(71) Applicant: SHINKO ELECTRIC INDUSTRIES CO., LTD., Nagano-shi (JP)

(72) Inventor: Yusuke Ono, Nagano (JP)

(21) Appl. No.: 19/392,743

(22) Filed: Nov. 18, 2025

(30) Foreign Application Priority Data
Dec. 6, 2024 (JP) 2024-214003

(51) Int. Cl. H05K 1/11

(52) U.S. Cl. CPC H05K 1/112

(57) ABSTRACT

A wiring board includes a wiring layer, an insulating layer, and an opening. The insulating layer is laminated on the wiring layer. The opening penetrates through the insulating layer to the wiring layer. A surface of the wiring layer includes a roughened portion that is formed in a region except for a region overlapping with a periphery of a bottom surface of the opening, and a roughness reduced portion that is formed in the region overlapping with the periphery of the bottom surface of the opening and that has lower surface roughness than the roughened portion.

### CROSS-REFERENCE TO RELATED APPLICATION

This application is based upon and claims the benefit of priority of the prior Japanese Patent Application No. 2024-214003, filed on Dec. 6, 2024, the entire contents of which are incorporated herein by reference.

### FIELD

The embodiment discussed herein is related to a wiring board and a wiring board manufacturing method.

### BACKGROUND

Conventionally, for example, a wiring board mounted with a semiconductor chip may have a multilayer wiring structure that is formed by using, for example, a semi-additive process. Specifically, a wiring layer is formed on an insulating layer by electroless plating and electrolytic plating, and an insulating layer that covers the wiring layer is further formed. In this manner, by repeatedly laminating the insulating layer and the wiring layer, a wiring board having a multilayer wiring structure is formed.

In the wiring board as described above, a wiring layer in an outermost layer of the multilayer wiring structure is covered by an insulating layer that is called a solder resist layer and that has insulating property. Further, a connecting terminal that penetrates through the insulating layer is formed if needed, so that it is possible to achieve electrical connection between the wiring layer in the outermost layer and an electronic component, such as a semiconductor chip, that is mounted on the insulating layer.

The connecting terminal is formed such that the wiring layer in the outermost layer is covered by the insulating layer, an opening that penetrates to the wiring layer is formed in the insulating layer by exposure and development, a seed layer is formed on a surface of the insulating layer including an inner wall surface of the opening by electroless plating, and electrolytic plating is performed on the seed layer.

Furthermore, in the wiring board having the multilayer wiring structure, in some cases, roughening treatment may be performed on a surface of the wiring layer in the outermost layer before the wiring layer is coveted by the insulating layer. By performing the roughening treatment on the surface of the wiring layer, the surface of the wiring layer becomes a roughened surface including concavities and convexities, and, by filling the roughened surface with a part of the insulating layer, it is possible to increase adhesion between the wiring layer and the insulating layer by the anchor effect.

Patent Literature 1: Japanese Laid-open Patent Publication No. 2007-317899

However, in the wiring board in which the surface of the wiring layer is subjected to the roughening treatment, it is difficult to maintain the adhesion between the wiring layer and the insulating layer and form an appropriate opening in the insulating layer, which is a problem. Specifically, when the opening is formed in the insulating layer by exposure and development, liquidity of a developing solution decreases due to frictional resistance of the roughened surface in the vicinity of a periphery of a bottom surface of the opening, so that residue of resin contained in the insulating layer is likely to remain in a flared shape. As a result, an opening of an appropriate shape is not formed in the insulating layer, and connection reliability between the connecting terminal and the wiring layer in the opening is reduced.

In contrast, it may be possible to cover the wiring layer by the insulating layer without performing roughening treatment on the surface of the wiring layer. However, in this case, the adhesion between the wiring layer and the insulating layer decreases and the insulating layer may be peeled off.

A wiring board disclosed in the present application includes, as one aspect, a wiring layer, an insulating layer, and an opening. The insulating layer is laminated on the wiring layer. The opening penetrates through the insulating layer to the wiring layer. A surface of the wiring layer includes a roughened portion that is formed in a region except for a region overlapping with a periphery of a bottom surface of the opening, and a roughness reduced portion that is formed in the region overlapping with the periphery of the bottom surface of the opening and that has lower surface roughness than the roughened portion.

### SUMMARY

According to an aspect of an embodiment, a wiring board includes a wiring layer; an insulating layer that is laminated on the wiring layer; and an opening that penetrates through the insulating layer to the wiring layer, wherein a surface of the wiring layer includes a roughened portion that is formed in another region except for a region overlapping with a periphery of a bottom surface of the opening; and a roughness reduced portion that is formed in the region overlapping with the periphery of the bottom surface of the opening and that has lower surface roughness than the roughened portion.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a wiring board according to one embodiment;

FIG. 2 is an enlarged view around a connecting terminal according to one embodiment;

FIG. 3 is a flowchart illustrating a method of manufacturing a semiconductor device according to one embodiment;

FIG. 4 is a diagram illustrating a specific example of a core board formation process;

FIG. 5 is a diagram illustrating a specific example of a build-up process;

FIG. 6 is a diagram illustrating a specific example of a solder resist layer formation process;

FIG. 7 is a diagram illustrating a specific example of a connecting terminal formation process;

FIG. 8 is a diagram illustrating a specific example of a semiconductor chip mounting process;

FIG. 9 is a flowchart illustrating a connecting terminal formation process according to one embodiment;

FIG. 10 is an enlarged view of a wiring layer of a topmost layer;

FIG. 11 is a diagram illustrating a specific example of a roughening treatment process;

FIG. 12 is a diagram illustrating a specific example of a roughness reduction treatment process;

FIG. 13 is a diagram illustrating an exterior of a surface of a pad when viewed from above;

FIG. 14 is a diagram illustrating a laminated state of a solder resist layer;

FIG. 15 is a diagram illustrating a specific example of an opening formation process;

FIG. 16 is a diagram illustrating a specific example of an electroless plating process;

FIG. 17 is a diagram illustrating a specific example of a DFR layer formation process;

FIG. 18 is a diagram illustrating a specific example of an electrolytic plating process;

FIG. 19 is a diagram illustrating a specific example of a DFR layer removal process;

FIG. 20 is an enlarged view around a connecting terminal according to a first modification of one embodiment;

FIG. 21 is a diagram illustrating roughness reduction treatment according to a modification;

FIG. 22 is a diagram illustrating an exterior of a surface of a pad when viewed from above;

FIG. 23 is an enlarged view of a periphery of a connecting terminal according to a second modification of one embodiment;

FIG. 24 is a flowchart illustrating a connecting terminal formation process according to the second modification of one embodiment;

FIG. 25 is a diagram illustrating a specific example of a solder ball mounting process; and

FIG. 26 is a diagram illustrating a specific example of a reflow process.

### DESCRIPTION OF EMBODIMENT

Embodiment of a wiring board and a wiring board manufacturing method disclosed in the present application will be described in detail below based on the drawings. The disclosed technology is not limited by the embodiment below.

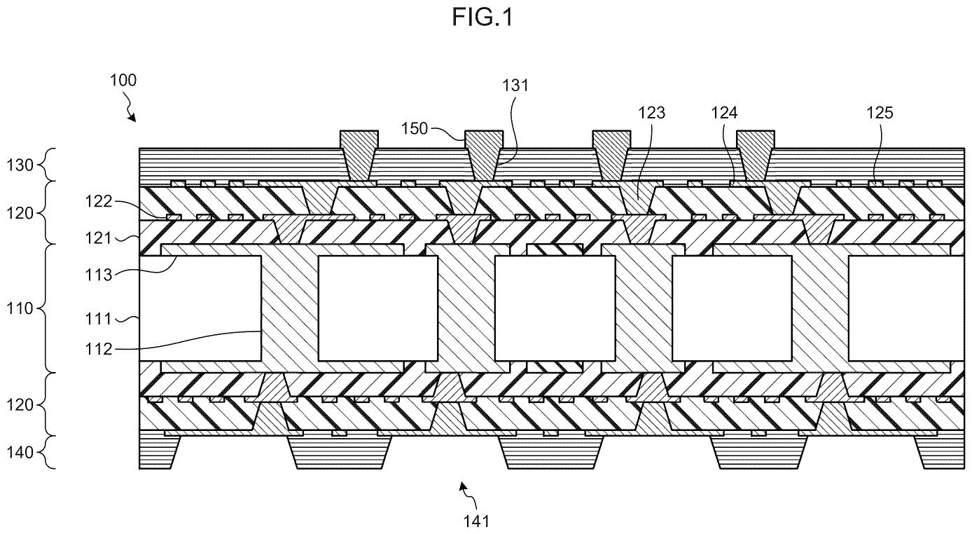

FIG. 1 is a diagram illustrating a configuration of a wiring board 100 according to one embodiment. FIG. 1 schematically illustrates a cross section of the wiring board 100. The wiring board 100 illustrated in FIG. 1 may be used as, for example, a substrate of a semiconductor device on which a semiconductor chip is mounted.

The wiring board 100 has a layered structure and includes a core board 110, a multilayer wiring structure 120, and solder resist layers 130 and 140. In the following, as illustrated in FIG. 1, explanation will be given based on the assumption that the solder resist layer 140 serves as a lowermost layer and the solder resist layer 130 serves as a topmost layer, but the wiring board 100 may be used upside down or may be used in an arbitrary posture, for example.

The core board 110 includes a base material 111 that is a plate-shaped insulator and wiring layers 113 that are formed on both surfaces of the base material 111 by metal plating. The wiring layers 113 on the both surfaces are connected to each other, if needed, by a through wiring 112 that penetrates through the base material 111.

The multilayer wiring structure 120 is a lamination of layers including an insulating layer 121 with insulating property and a wiring layer 122 with conductivity. The insulating layer 121 is formed by using, for example, insulating non-photosensitive resin, such as epoxy resin and polyimide resin. Further, the wiring layer 122 is formed by using, for example, metal, such as copper or a copper alloy. In FIG. 1, two layers are laminated in the multilayer wiring structure 120 on the upper side of the core board 110, and two layers are laminated in the multilayer wiring structure 120 on the lower side of the core board 110; however, the number of laminated layers may be one or three or more. The wiring layers 113 and 122 that are adjacent to each other across the insulating layer 121 are connected, if needed, by vias 123 that penetrate through the insulating layer 121.

In the wiring layer 122 of the topmost layer, a pad 124 that is connected to a connecting terminal 150 for a semiconductor chip and a wiring pattern 125 that is located in the vicinity of the pad 124 are formed. As will be described later, a surface of the wiring layer 122 of the topmost layer is entirely roughened, but in the vicinity of a periphery of a bottom surface of an opening 131 formed in the solder resist layer 130, surface roughness of a surface of the wiring layer 122 is locally reduced.

The solder resist layer 130 is a layer that covers the wiring layer 122 of the topmost layer of the multilayer wiring structure 120 and protects wiring. The solder resist layer 130 is, for example, a layer that is made of insulating photosensitive resin, such as acrylic resin or polyimide resin, and is one of insulating layers.

A surface of the wiring board 100 at the side of the solder resist layer 130 is, for example, a surface on which an electronic component, such as a semiconductor chip, is mounted. At a position at which a semiconductor chip is mounted, the opening 131 is formed in the solder resist layer 130. The solder resist layer 130 is formed by using photosensitive resin, and therefore, it is possible to form the opening 131 by exposure and development. Further, in the opening 131, the connecting terminal 150 for connecting the wiring layer 122 of the multilayer wiring structure 120 and an electrode of a semiconductor chip is formed. Specifically, the pad 124 is exposed from the bottom surface of the opening 131, and the connecting terminal 150 is connected to the pad 124.

The solder resist layer 140 is, similarly to the solder resist layer 130, a layer that covers the wiring layer 122 on the surface of the multilayer wiring structure 120 and protects wiring. The solder resist layer 140 is, for example, a layer that is made of insulating photosensitive resin, such as acrylic resin or polyimide resin, and is one of insulating layers.

A surface of the wiring board 100 at the side of the solder resist layer 140 is a surface that is connected to an external component or an apparatus. At a position at which an external connecting terminal that is electrically connected to an external component or an apparatus is formed, an opening 141 is formed in the solder resist layer 140, and the wiring layer 122 of the multilayer wiring structure 120 is exposed from the opening 141. In the opening 141, for example, an external connecting terminal, such as a solder ball, is formed. The solder resist layer 140 is formed by using photosensitive resin, and therefore, it is possible to form the opening 141 by exposure and development.

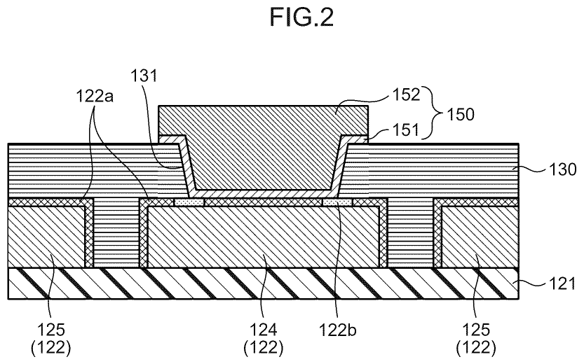

FIG. 2 is an enlarged view around the connecting terminal 150 according to one embodiment. In FIG. 2, a connected portion between the connecting terminal 150 and the wiring layer 122 of the topmost layer of the multilayer wiring structure 120 and around the connected portion are illustrated in an enlarged manner.

As illustrated in FIG. 2, the connecting terminal 150 includes a seed layer 151 that is an electroless plating film formed by electroless plating, and a post 152 that is an electrolytic plating film formed on the seed layer 151 by electrolytic plating. Further, a surface of the wiring layer 122 is entirely roughened and a roughened portion 122a is formed. However, in the vicinity of the periphery of the bottom surface of the opening 131 formed in the solder resist layer 130, the surface roughness of the surface of the wiring layer 122 is locally reduced and a roughness reduced portion 122b is formed.

Specifically, the roughened portion 122a is formed in a region except for the region that overlaps with the periphery of the bottom surface of the opening 131 on the surface of the wiring layer 122, and the roughness reduced portion 122b with lower surface roughness than the roughened portion 122a is formed in the region that overlaps with the periphery of the bottom surface of the opening 131 on the surface of the wiring layer 122. Concavities and convexities included in the roughened portion 122a are filled with a part of the solder resist layer 130, so that adhesion between the wiring layer 122 and the solder resist layer 130 is increased by the anchor effect. The roughness reduced portion 122b has smaller frictional resistance as compared to the roughened portion 122a in a direction parallel to the surface of the wiring layer 122; therefore, in the vicinity of the periphery of the bottom surface of the opening 131, it is possible to prevent reduction in liquidity of a developing solution that is used for formation of the opening 131. With this configuration, residue of resin contained in the solder resist layer 130 is less likely to remain in the vicinity of the periphery of the bottom surface of the opening 131, so that the opening 131 of an appropriate shape is formed in the solder resist layer 130. As a result, it is possible to form the appropriate opening 131 in the solder resist layer 130 while maintaining the adhesion between the wiring layer 122 and the solder resist layer 130. In other words, it is possible to improve connection reliability between the connecting terminal 150 and the wiring layer 122 in the opening 131 without causing the solder resist layer 130 to peel off from the wiring layer 122.

Furthermore, the roughened portion 122a is formed in a region except for a region that overlaps with the periphery of the bottom surface of the opening 131 on a surface of the pad 124 included in the wiring layer 122 and on a surface of the wiring pattern 125. The roughness reduced portion 122b is formed in the region that overlaps with the periphery of the bottom surface of the opening 131 on the surface of the pad 124. The roughness reduced portion 122b is formed in only a partial region on the surface of the pad 124 and the roughened portion 122a is formed on the other region on the surface of the pad 124 and the surface of the wiring pattern 125, so that it is possible to stably maintain the adhesion between the wiring layer 122 and the solder resist layer 130.

Meanwhile, in the example illustrated in FIG. 2, the roughness reduced portion 122b is formed in a region that overlaps with the periphery of the bottom surface of the opening 131 but does not overlap with the center of the bottom surface of the opening 131 on the surface of the wiring layer 122. In other words, the roughness reduced portion 122b is not formed in the region that overlaps with the center of the bottom surface of the opening 131 on the surface of the wiring layer 122, and, in this region, the roughened portion 122a is formed.

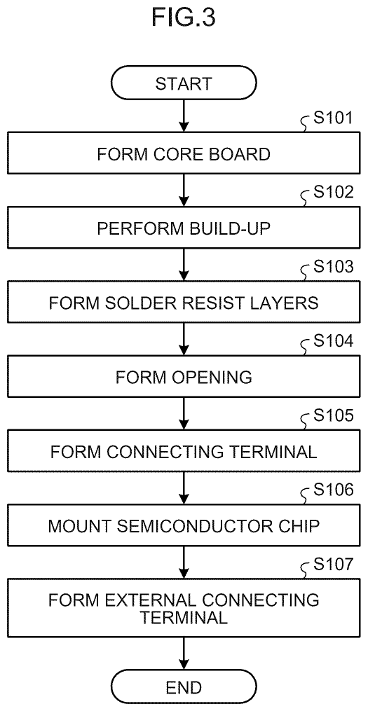

A method of manufacturing a semiconductor device including the wiring board 100 configured as described above will be described below with a specific example with reference to FIG. 3. FIG. 3 is a flowchart illustrating the method of manufacturing the semiconductor device according to one embodiment.

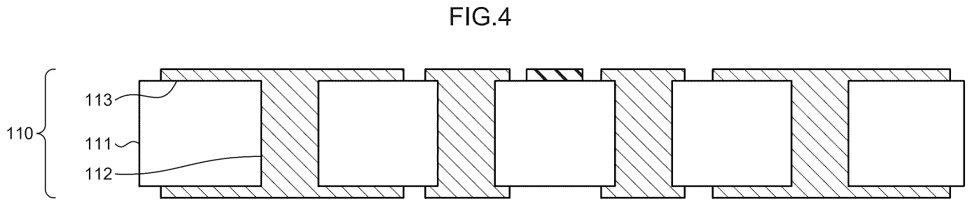

First, the core board 110 that serves as a support member of the wiring board 100 is formed (Step S101). Specifically, for example, as illustrated in FIG. 4, the through wiring 112 that penetrates through the base material 111 is formed in the base material 111 that is a plate-shaped insulator, and wiring layers 113 made of metal, such as copper or a copper alloy, are formed on the both surfaces of the base material 111 by copper foil or copper plating. FIG. 4 is a diagram illustrating a specific example of a core board formation process. The wiring layers 113 on the both surfaces of the base material 111 are connected, if needed, to the through wiring 112 that is formed by, for example, plating with metal, such as copper or a copper alloy. As the base material 111, for example, a reinforcing member, such as glass woven fabric, that is impregnated with insulating resin, such as epoxy resin, may be used. As the reinforcing member, a glass non-woven fabric, an aramid woven fabric, an aramid non-woven fabric, or the like may be used, rather than the glass woven fabric. Further, as the insulating resin, it is possible to use polyimide resin, cyanate resin, or the like.

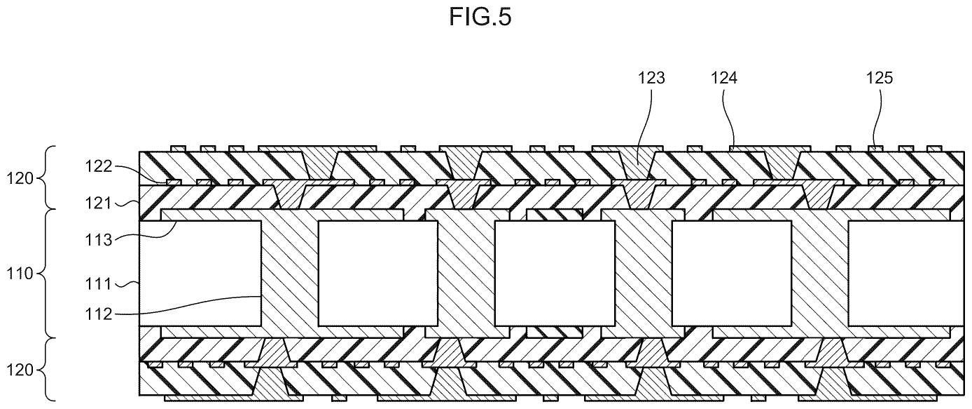

Furthermore, the multilayer wiring structures 120 are formed on an upper surface and a lower surface of the core board 110 by the build-up method (Step S102). Specifically, for example, as illustrated in FIG. 5, the insulating layers 121 are formed on the upper surface and the lower surface of the core board 110, and the wiring layers 122 are formed on the surfaces of the insulating layers 121. FIG. 5 is a diagram illustrating a specific example of a build-up process. The insulating layers 121 are formed by using, for example, insulating non-photosensitive resin, such as epoxy resin and polyimide resin. Furthermore, the wiring layers 122 are formed by, for example, the semi-additive process by plating with metal, such as copper or a copper alloy.

The wiring layers 113 of the core board 110 and the wiring layers 122 or the adjacent wiring layers 122 are connected, if needed, for example, by the vias 123 that are formed by plating with metal, such as copper or a copper alloy. It may be possible to laminate the plurality of insulating layers 121 and the plurality of wiring layers 122 on each of the upper surface and the lower surface of the core board 110. On the wiring layer 122 of the topmost layer, the pad 124 that is connected to the connecting terminal 150 for a semiconductor chip and the wiring pattern 125 that is located in the vicinity of the pad 124 are formed.

When the multilayer wiring structure 120 is formed by the build-up method, roughening treatment for roughening the entire surface of the wiring layer 122 of the topmost layer of the multilayer wiring structure 120 is performed. Specifically, for example, the entire surface of the wiring layer 122 of the topmost layer is roughened by an organic acid-based pharmaceutical solution, so that the roughened portion 122a is formed. When the roughened portion 122a is formed, roughness reduction treatment for reducing surface roughness of a part of the surface of the wiring layer 122 is performed. Specifically, in the vicinity of the periphery of the bottom surface of the opening 131 that is formed in the solder resist layer 130, for example, the surface roughness of the surface of the wiring layer 122 is locally reduced by laser processing, so that the roughness reduced portion 122b is formed.

Moreover, the wiring layer 122 of an outermost layer of the multilayer wiring structure 120 is covered by the solder resist layers 130 and 140 (Step S103). Specifically, the wiring layer 122 of the topmost layer of the multilayer wiring structure 120 is covered by the solder resist layer 130 that is laminated on the upper surface of the core board 110, and the wiring layer 122 of a lowermost layer of the multilayer wiring structure 120 laminated on the lower surface of the core board 110 is covered by the solder resist layer 140. The solder resist layers 130 and 140 are made of, for example, insulating photosensitive resin, such as acrylic resin or polyimide resin.

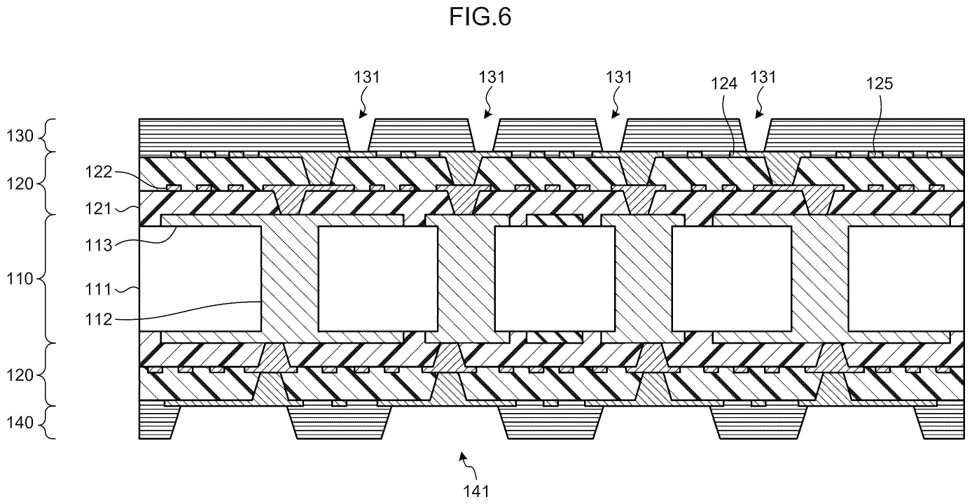

Furthermore, for example, as illustrated in FIG. 6, in the solder resist layer 130 at a side at which a semiconductor chip is mounted, the opening 131 is formed at a position at which the connecting terminal 150 for a semiconductor chip is provided (Step S104). FIG. 6 is a diagram illustrating a specific example of a solder resist layer formation process. The wiring layer 122 of the topmost layer of the multilayer wiring structure 120 is exposed from the bottom surface of the opening 131. In contrast, in the solder resist layer 140 at a side at which an external component or an apparatus is connected, the opening 141 is formed at a position at which the external connecting terminal is arranged. The wiring layer 122 of the lowermost layer of the multilayer wiring structure 120 is exposed from the bottom surface of the opening 141.

The solder resist layers 130 and 140 are formed of photosensitive resin, and therefore, it is possible to form the openings 131 and 141 by exposure and development.

At the time of formation of the opening 131 by development, the opening 131 penetrates to the wiring layer 122 of the topmost layer of the multilayer wiring structure 120; however, the roughness reduced portion 122b is formed on the surface of the wiring layer 122 in the vicinity of the periphery of the bottom surface of the opening 131, so that it is possible to prevent decrease of liquidity of a developing solution. Therefore, in the vicinity of the periphery of the bottom surface of the opening 131, residue of resin contained in the solder resist layer 130 is less likely to remain, so that the opening 131 of an appropriate shape is formed in the solder resist layer 130.

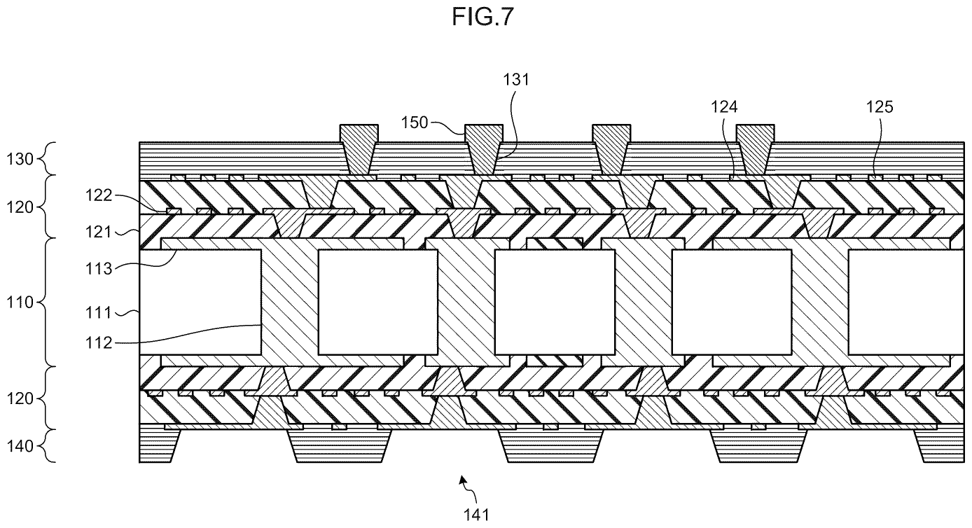

Furthermore, the connecting terminal 150 is formed in the opening 131 of the solder resist layer 130 (Step S105). Specifically, a seed layer is formed on the surface of the solder resist layer 130 by, for example, electroless copper plating, and electrolytic copper plating is performed on the seed layer at the position of the opening 131 for example, so that the connecting terminal 150 including the seed layer 151 and the post 152 is formed. The connecting terminal 150 is, for example, as illustrated in FIG. 7, connected to the wiring layer 122 of the topmost layer of the multilayer wiring structure 120 at the position of the opening 131 of the solder resist layer 130. FIG. 7 is a diagram illustrating a specific example of a connecting terminal formation process. The seed layer 151 may be formed by metal sputtering using copper or the like. At the time of forming the connecting terminal 150, the post 152 is formed by electrolytic copper plating on the seed layer 151, and thereafter, the seed layer in an unneeded portion is removed by etching. Meanwhile, formation of the connecting terminal 150 will be described in detail later.

By formation of the connecting terminal 150, the wiring board 100 is completed. Further, a semiconductor chip is mounted on the wiring board 100 at the side of the solder resist layer 130 (Step S106), and the connecting terminal 150 and the electrode of the semiconductor chip are connected to each other.

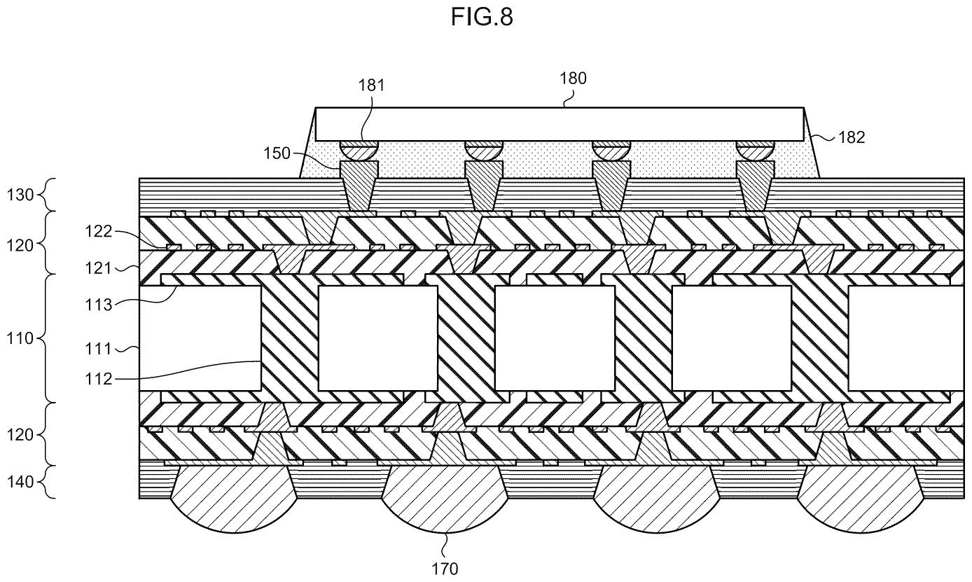

Specifically, for example, as illustrated in FIG. 8, a semiconductor chip 180 is mounted on an upper side of the connecting terminal 150. FIG. 8 is a diagram illustrating a specific example of a semiconductor chip mounting process. In the semiconductor chip 180, an electrode 181 is bonded to the connecting terminal 150 by, for example, solder, and a bonding portion between the electrode 181 and the connecting terminal 150 are sealed by underfill resin 182 for mounting on the wiring board 100. Subsequently, an external connecting terminal, such as a solder ball 170, is formed on the opening 141 of the solder resist layer 140 (Step S107). Meanwhile, the process of mounting the semiconductor chip 180 and the process of forming the external connecting terminal as described above may be performed in inverted order. Furthermore, it may be possible to adopt, as the external connecting terminal, a portion corresponding to the wiring layer 122 exposed from the opening 141 of the solder resist layer 140 without arranging the solder ball 170.

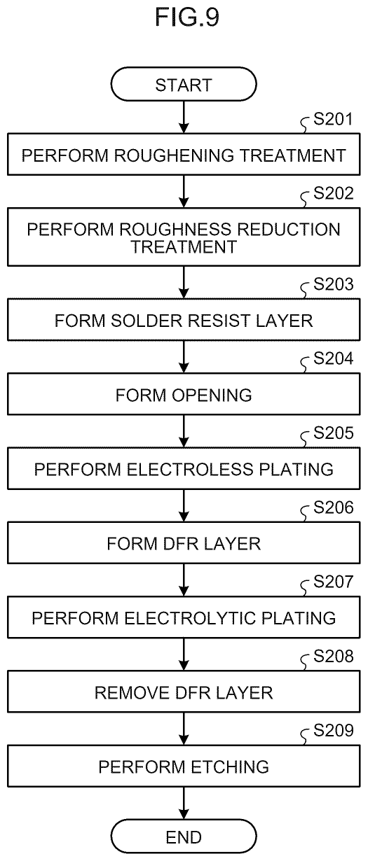

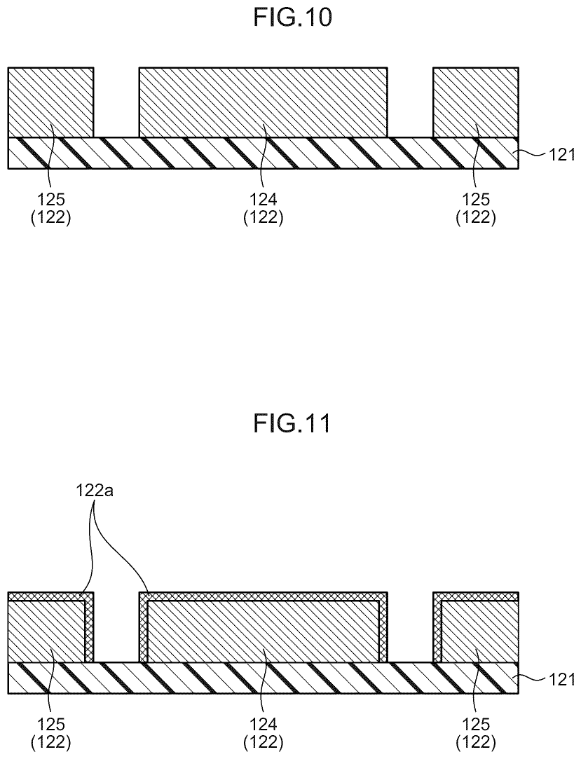

A process of forming the connecting terminal 150 will be described in detail below with reference to FIG. 9. FIG. 9 is a flowchart illustrating a connecting terminal formation process according to one embodiment. In the following, for example, a series of steps for covering the wiring layer 122 of the topmost layer of the multilayer wiring structure 120 illustrated in FIG. 10 by the solder resist layer 130 and forming the connecting terminal 150 in the solder resist layer 130 will be described. FIG. 10 is an enlarged view of the wiring layer 122 of the topmost layer.

When the multilayer wiring structure 120 is formed, the roughening treatment for roughening the entire surface of the wiring layer 122 of the topmost layer of the multilayer wiring structure 120 is performed (Step S201). Specifically, for example, as illustrated in FIG. 11, the entire surface of the wiring layer 122 of the topmost layer is roughened by an organic acid-based pharmaceutical solution, so that the roughened portion 122a is formed. In other words, the roughened portion 122a is formed on the surface of the pad 124 and the surface of the wiring pattern 125 included in the wiring layer 122. FIG. 11 is a diagram illustrating a specific example of a roughening treatment process.

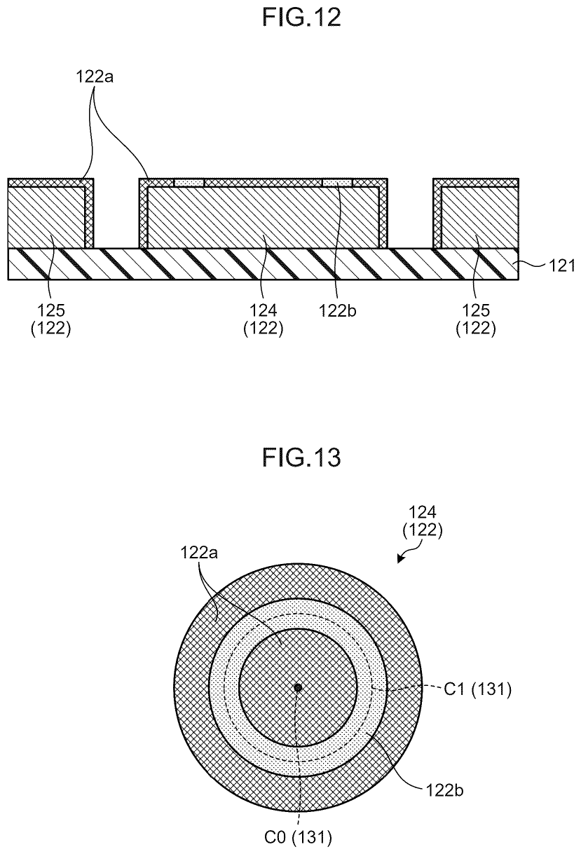

When the roughened portion 122a is formed in the surface of the wiring layer 122 of the topmost layer, the roughness reduction treatment for reducing surface roughness of a part of the surface of the wiring layer 122 is performed (Step S202). Specifically, in the vicinity of the periphery of the bottom surface of the opening 131 that is formed in the solder resist layer 130, for example, as illustrated in FIG. 12, the surface roughness of the surface of the wiring layer 122 is locally reduced by laser processing, so that the roughness reduced portion 122b is formed. FIG. 12 is a diagram illustrating a specific example of a roughness reduction treatment process. The roughness reduced portion 122b is formed by, for example, laser processing. For example, CO₂ laser, UV laser, or the like is used for the laser processing, and the laser is applied to a region overlapping with the periphery of the bottom surface of the opening 131 on the surface of the wiring layer 122, so that the surface roughness is reduced. Specifically, in the roughness reduction treatment, a convex portion among concavities and convexities in the roughened portion 122a is melted by application of the laser to reduce a protrusion amount of the convex portion and reduce the surface roughness. In other words, the roughness reduced portion 122b is formed in the region overlapping with the periphery of the bottom surface of the opening 131 on the surface of the wiring layer 122, where the surface roughness is reduced as compared to the other roughened portion 122a.

Specifically, arithmetic mean roughness Ra indicating surface roughness of the roughened portion 122a is, for example, equal to or larger than 300 nanometers (nm) and equal to or smaller than 600 nm, and arithmetic mean roughness Ra indicating surface roughness of the roughness reduced portion 122b is, for example, smaller than 300 nm. The surface roughness of the roughness reduced portion 122b is smaller than the surface roughness of the roughened portion 122a, so that, in the roughness reduced portion 122b, frictional resistance in a direction parallel to the surface of the wiring layer 122 is reduced.

The roughness reduced portion 122b is formed in, for example, as illustrated in FIG. 13, a region that overlaps with a periphery C1 of the bottom surface of the opening 131 and that does not overlap with a center C0 of the bottom surface of the opening 131 in the surface of the wiring layer 122. FIG. 13 is a diagram illustrating an exterior of the surface of the pad 124 when viewed from above. Specifically, for example, as illustrated in FIG. 13, the pad 124 and the opening 131 have circular shapes in plan view, and the roughness reduced portion 122b is formed in a ring-shaped region that spreads toward an inner side and an outer side in the radial direction of the opening 131 from the periphery C1 of the bottom surface of the opening 131. An inner periphery of the roughness reduced portion 122b is located on the inner side in the radial direction of the opening 131 relative to the periphery C1 of the bottom surface of the opening 131, and an outer periphery of the roughness reduced portion 122b is located on the outer side in the radial direction of the opening 131 relative to the periphery C1 of the bottom surface of the opening 131. A diameter of the inner periphery of the roughness reduced portion 122b is about 10 micrometers (μm) smaller than a diameter of the periphery C1 of the bottom surface of the opening 131, and a diameter of the outer periphery of the roughness reduced portion 122b is about 10 μm larger than the periphery C1 of the bottom surface of the opening 131.

In this manner, the roughness reduced portion 122b is formed in the ring-shaped region that spreads inward and outward from the periphery C1 of the bottom surface of the opening 131, so that, in the vicinity of the center C0 of the bottom surface of the opening 131, the roughened portion 122a remains without reducing the surface roughness of the surface of the wiring layer 122.

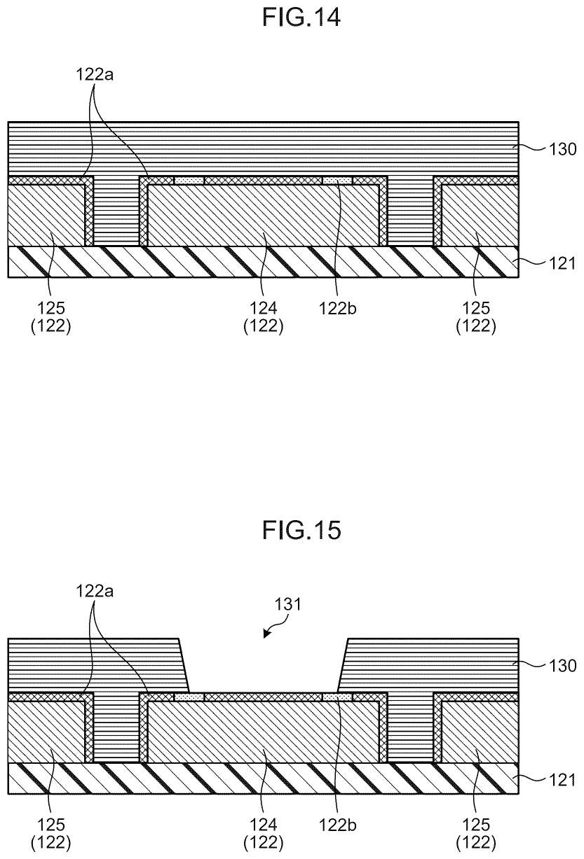

When the roughness reduced portion 122b is formed in the vicinity of the periphery of the bottom surface of the opening 131, the wiring layer 122 of the topmost layer of the multilayer wiring structure 120 is covered by the solder resist layer 130 (Step S203). Specifically, for example, as illustrated in FIG. 14, the solder resist layer 130 is laminated so as to cover the surface of the wiring layer 122 including the roughened portion 122a and the roughness reduced portion 122b. FIG. 14 is a diagram illustrating a laminated state of the solder resist layer 130. The solder resist layer 130 is made of, for example, insulating photosensitive resin, such as acrylic resin or polyimide resin.

When the solder resist layer 130 is formed by using photosensitive resin, the opening 131 is formed in the solder resist layer 130 (Step S204). Specifically, for example, as illustrated in FIG. 15, the opening 131 is formed in the solder resist layer 130 at a position at which the pad 124 of the wiring layer 122 is disposed. FIG. 15 is a diagram illustrating a specific example of an opening formation process. The pad 124 of the wiring layer 122 is exposed from the bottom surface of the opening 131.

The solder resist layer 130 is formed of photosensitive resin, and therefore, it is possible to form the opening 131 by exposure and development.

At the time of formation of the opening 131 by development, the opening 131 penetrates to the wiring layer 122 of the topmost layer of the multilayer wiring structure 120; however, the roughness reduced portion 122b is formed on the surface of the wiring layer 122 in the vicinity of the periphery of the bottom surface of the opening 131, so that it is possible to prevent decrease of liquidity of a developing solution. Therefore, in the vicinity of the periphery of the bottom surface of the opening 131, residue of resin contained in the solder resist layer 130 is less likely to remain, so that the opening 131 of an appropriate shape is formed in the solder resist layer 130.

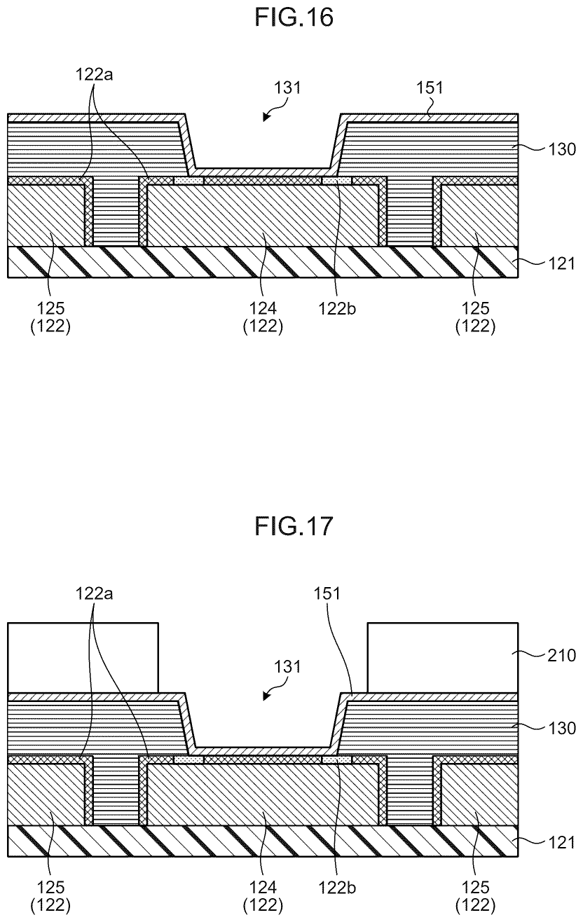

When the opening 131 is formed in the solder resist layer 130, the seed layer 151 is formed by electroless plating (Step S205). Specifically, for example, as illustrated in FIG. 16, the seed layer 151 is formed by performing electroless copper plating on the surface of the solder resist layer 130 for example. FIG. 16 is a diagram illustrating a specific example of an electroless plating process. A thickness of the seed layer 151 is, for example, about 0.5 to 1.5 μm. The seed layer 151 covers the surface of the solder resist layer 130 and an upper surface of the wiring layer 122 (the pad 124) exposed from the opening 131. The seed layer 151 may be formed by metal sputtering using copper or the like.

When the seed layer 151 is formed, a dry film resist (DFR) layer serving as a mask for electrolytic plating is formed (Step S206). Specifically, the DFR is laminated on the seed layer 151 and exposure and development are performed in accordance with the position of the connecting terminal 150, so that, for example, as illustrated in FIG. 17, a DFR 210 is formed on the seed layer 151 in a portion other than the position at which the connecting terminal 150 is formed. FIG. 17 is a diagram illustrating a specific example of a DFR layer formation process.

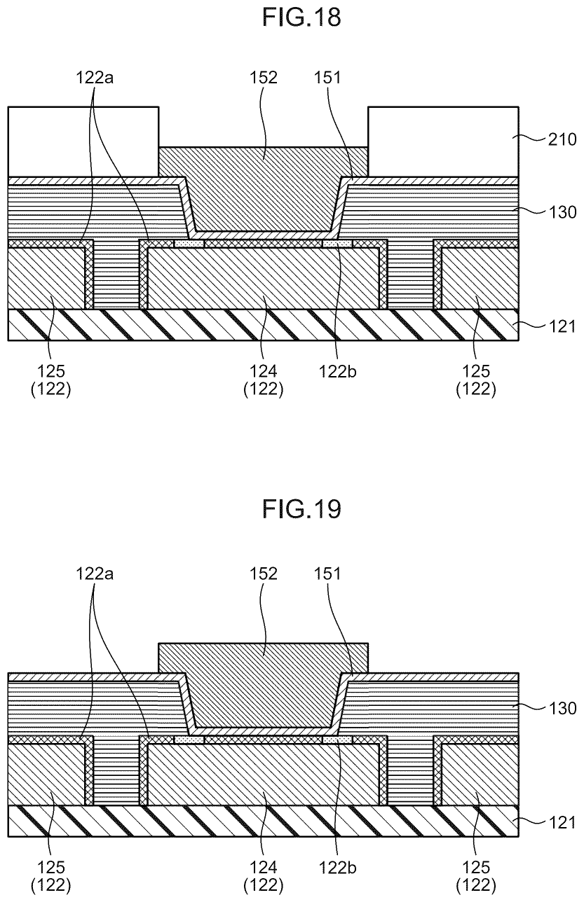

Furthermore, by performing electrolytic plating, the post 152 is formed on the seed layer 151 (Step S207). Specifically, for example, electrolytic plating is performed by using a copper sulfate plating solution, so that copper is precipitated in a portion where the DFR 210 is not formed, so that, for example, as illustrated in FIG. 18, the post 152 is formed on the seed layer 151. In this case, the opening 131 is filled with electrolytic plating. FIG. 18 is a diagram illustrating a specific example of an electrolytic plating process.

When the post 152 is formed, the DFR 210 is removed (Step S208). To remove the DFR 210, for example, caustic soda or an amine-type alkaline stripping solution is used. By removing the DFR 210, for example, as illustrated in FIG. 19, the post 152 protrudes from the solder resist layer 130 and is connected to the wiring layer 122 via the seed layer 151. FIG. 19 is a diagram illustrating a specific example of a DFR layer removal process. At this stage, the seed layer 151 remains over the entire surface and the post 152 is short-circuited to a different post; therefore, it is needed to remove the seed layer 151 in an unneeded portion that does not overlap with the post 152.

To cope with this, etching is performed on the seed layer 151 by using the post 152 as a mask (Step S209). Specifically, the seed layer 151 formed on the upper surface of the solder resist layer 130 is immersed in, for example, an etching solution that selectively dissolves copper, so that the seed layer 151 in an unneeded portion that does not overlap with the post 152 is removed. Consequently, at the position of the opening 131, the connecting terminal 150 that is connected to the wiring layer 122 and that includes the seed layer 151 and the post 152 is formed.

The opening 131 has an appropriate shape and less resin residue remains in the vicinity of the periphery of the bottom surface of the opening 131, so that adhesion between the connecting terminal 150 and the wiring layer 122 is less likely to be damaged by the resin residue. Therefore, the connecting terminal 150 is reliably fixed to the surface of the wiring layer 122 and it is possible to improve connection reliability between the connecting terminal 150 and the wiring layer 122.

### Modification

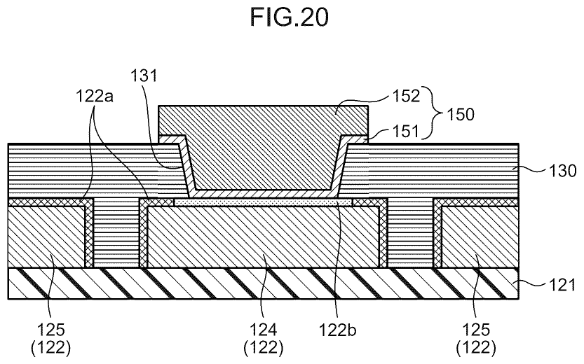

Modifications of one embodiment will be described below with reference to FIG. 20 to FIG. 26. Meanwhile, in the modifications described below, the same components as those of the above-described embodiment are denoted by the same reference symbols, and repeated explanation will be omitted appropriately.

### First Modification

FIG. 20 is an enlarged view around the connecting terminal 150 according to a first modification of one embodiment. In FIG. 20, a periphery of a connected portion between the connecting terminal 150 and the wiring layer 122 of the topmost layer of the multilayer wiring structure 120 is illustrated in an enlarged manner.

As illustrated in FIG. 20, in the wiring board 100 according to the first modification, the roughness reduced portion 122b is formed in a region that overlaps with the periphery of the bottom surface of the opening 131 and the center of the bottom surface of the opening 131 on the surface of the wiring layer 122. In other words, the roughness reduced portion 122b is formed in a region that overlaps with the entire bottom surface of the opening 131 on the surface of the wiring layer 122.

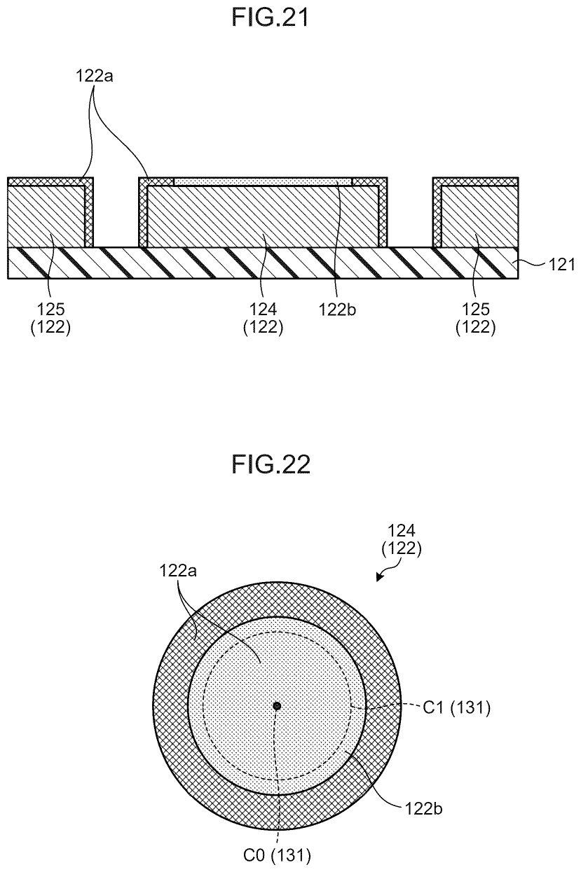

Roughness reduction treatment for forming the roughness reduced portion 122b illustrated in FIG. 20 will be described below. FIG. 21 is a diagram illustrating the roughness reduction treatment according to the modification. In the roughness reduction treatment according to the modification, laser is applied to the region that overlaps with the periphery of the bottom surface of the opening 131 and the center of the bottom surface of the opening 131 on the surface of the wiring layer 122 and surface roughness is reduced. In other words, the roughness reduced portion 122b is formed in the region that overlaps with the periphery of the bottom surface of the opening 131 and the center of the bottom surface of the opening 131 on the surface of the wiring layer 122, so that the surface roughness is reduced as compared to the roughened portion 122a.

The roughness reduced portion 122b is formed in, for example, as illustrated in FIG. 22, a region that overlaps with the periphery C1 of the bottom surface of the opening 131 and the center C1 of the bottom surface of the opening 131 on the surface of the wiring layer 122. FIG. 22 is a diagram illustrating an exterior of a surface of the pad 124 when viewed from above. Specifically, for example, as illustrated in FIG. 22, the pad 124 and the opening 131 have circular shapes in plan view, and the roughness reduced portion 122b is formed in a circular region that spreads from the center C0 of the bottom surface of the opening 131 toward an outer side in a radial direction of the opening 131 relative to the periphery C1 of the bottom surface of the opening 131. An outer periphery of the roughness reduced portion 122b is located on the outer side of the periphery C1 of the bottom surface of the opening 131 in the radial direction of the opening 131. A diameter of the outer periphery of the roughness reduced portion 122b is about 10μm larger than the diameter of the periphery C1 of the bottom surface of the opening 131.

In this manner, in the first modification, the roughness reduced portion 122b is formed in the region that overlaps with the entire bottom surface of the opening 131, so that it is possible to reduce the accuracy of positional alignment of the opening 131 with respect to the roughness reduced portion 122b and it is possible to simplify formation of the opening 131.

### Second Modification

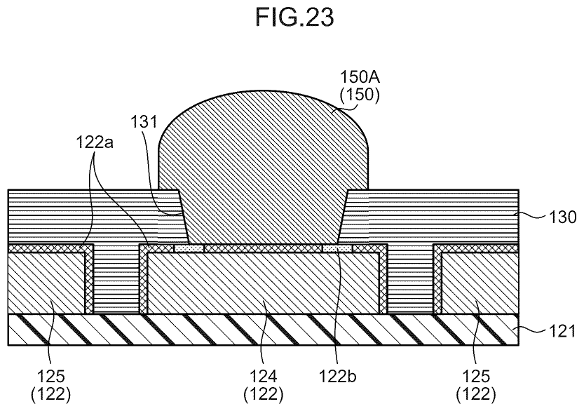

FIG. 23 is an enlarged view of a periphery of the connecting terminal 150 according to a second modification of one embodiment. In FIG. 23, a periphery of a connected portion between the connecting terminal 150 and the wiring layer 122 of the topmost layer of the multilayer wiring structure 120 is illustrated in an enlarged manner.

As illustrated in FIG. 23, in the wiring board 100 according to the second modification, the connecting terminal 150 may be formed as a solder bump 150A.

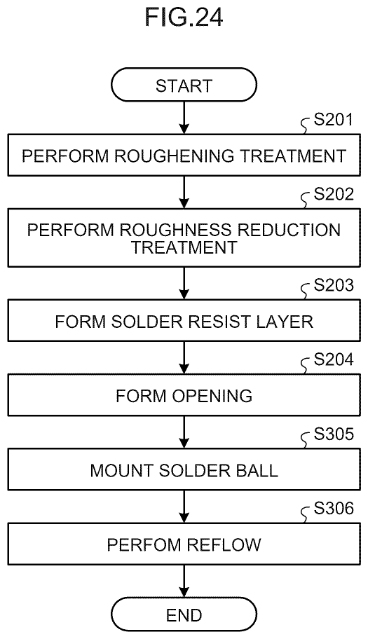

A process of forming the connecting terminal 150 as the solder bump 150A will be described below with reference to FIG. 24. FIG. 24 is a flowchart illustrating a specific example of the connecting terminal formation process according to the second modification of one embodiment. In FIG. 24, Step S201 to Step S204 are the same as Step S201 to Step S204 illustrated in FIG. 9, and therefore, detailed explanation thereof will be omitted.

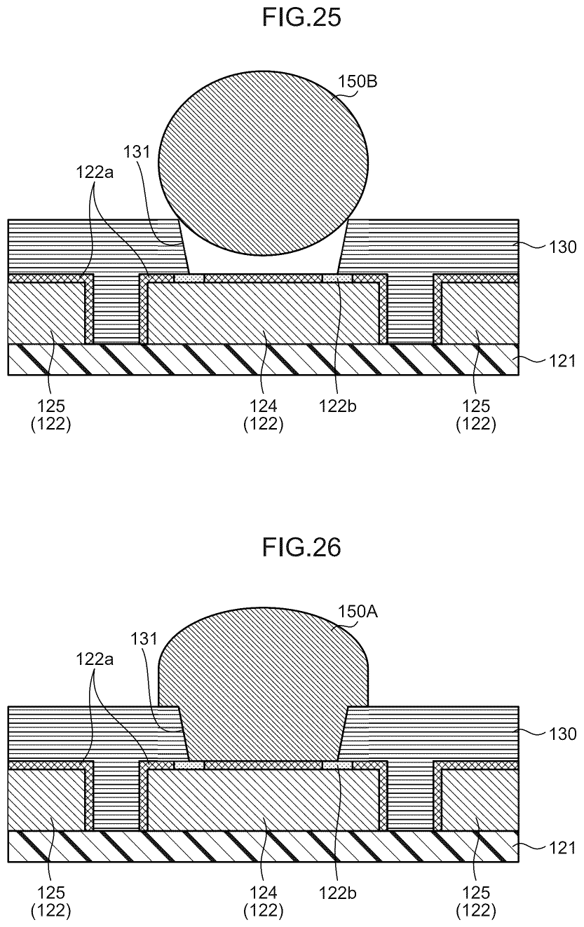

When the opening 131 is formed in the solder resist layer 130 (Step S204), for example, as illustrated in FIG. 25, a solder ball 150B is mounted on the solder resist layer 130 at the position of the opening 131 (Step S305). FIG. 25 is a diagram illustrating a specific example of a solder ball mounting process. The solder ball 150B is mounted by, for example, a transfer method or the like. As the solder ball 150B, for example, an alloy of tin (Sn), silver (Ag), and cupper (Cu) or the like may be used.

When the solder ball 150B is mounted, reflow at reflow temperature for melting the solder ball 150B is performed (Step S306). Specifically, the solder ball 150B is melted at high temperature and thereafter cooled to solidify the solder ball 150B. With this configuration, for example, as illustrated in FIG. 26, the solder bump 150A in which an upper surface protrudes in a spherical shape on the pad 124 and a base portion (root portion) is stored in the opening 131. FIG. 26 is a diagram illustrating a specific example of a reflow process.

In this manner, even when the connecting terminal 150 is formed as the solder bump 150A, the opening 131 has an appropriate shape and less resin residue remains in the vicinity of the periphery of the bottom surface of the opening 131, so that adhesion between the connecting terminal 150 and the wiring layer 122 is less likely to be damaged by the resin residue. Therefore, the connecting terminal 150 is securely fixed to the surface of the wiring layer 122, so that it is possible to increase connection reliability between the connecting terminal 150 and the wiring layer 122.

Meanwhile, it may be possible to adopt the solder bump 150A as the connecting terminal 150 in the first modification.

As described above, a wiring board (for example, the wiring board 100) according to one embodiment includes a wiring layer (for example, the wiring layer 122), an insulating layer (for example, the solder resist layer 130), and an opening (for example, the opening 131). The insulating layer is laminated on the wiring layer. The opening penetrates through the insulating layer to the wiring layer. A surface of the wiring layer includes a first roughened portion that is formed in a region except for a region overlapping with a periphery (for example, the periphery C1) of a bottom surface of the opening and a roughness reduced portion that is formed in the region overlapping with the periphery of the bottom surface of the opening and that has lower surface roughness than the first roughened portion. With this configuration, it is possible to maintain adhesion between the wiring layer and the insulating layer and form an appropriate opening in the insulating layer.

According to one embodiment of the wiring board disclosed in the present application, it is possible to maintain adhesion between a wiring layer and an insulating layer and form an appropriate opening in the insulating layer.

(Note) (1) A wiring board manufacturing method comprising:
forming a wiring layer;
roughening a surface of the wiring layer;
reducing surface roughness of a part of the surface of the wiring layer;
laminating an insulating layer on the wiring layer; and
forming an opening that penetrates through the insulating layer to the wiring layer, wherein
the reducing includes reducing surface roughness of a region overlapping with a periphery of a bottom surface of the opening on the surface of the wiring layer.

(2) The wiring board manufacturing method according to the (1), wherein the reducing includes reducing surface roughness of the region overlapping with the periphery of the bottom surface of the opening on the surface of the wiring by applying laser to the region.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A wiring board comprising:
a wiring layer;
an insulating layer that is laminated on the wiring layer; and
an opening that penetrates through the insulating layer to the wiring layer, wherein
a surface of the wiring layer includes
a roughened portion that is formed in another region except for a region overlapping with a periphery of a bottom surface of the opening; and
a roughness reduced portion that is formed in the region overlapping with the periphery of the bottom surface of the opening and that has lower surface roughness than the roughened portion.

2. The wiring board according to claim 1, wherein the roughness reduced portion is formed in a region that overlaps with the periphery of the bottom surface of the opening and that does not overlap with a center of the bottom surface of the opening.

3. The wiring board according to claim 1, wherein the roughness reduced portion is formed in a ring-shaped portion that spreads toward an inner side and an outer side in a radial direction of the opening from the periphery of the bottom surface of the opening.

4. The wiring board according to claim 1, wherein the roughness reduced portion is formed in a region that overlaps with the periphery of the bottom surface of the opening and a center of the bottom surface of the opening.

5. The wiring board according to claim 1, wherein the roughness reduced portion is formed in a circular region that spreads from a center of the bottom surface of the opening toward an outer side in a radial direction of the opening relative to the periphery of the bottom surface of the opening.

6. The wiring board according to claim 1, wherein
arithmetic mean roughness indicating surface roughness of the roughened portion is equal to or larger than 300 nanometers (nm) and equal to or smaller than 600 nm, and
arithmetic mean roughness indicating surface roughness of the roughness reduced portion is smaller than 300 nm.

7. The wiring board according to claim 1, wherein
the wiring layer includes
a pad; and
a wiring pattern that is located in a vicinity of the pad,
the opening penetrates through the insulating layer to the pad,
the roughened portion is formed in another region except for a region overlapping with the periphery of the bottom surface of the opening on a surface of the pad and a surface of the wiring pattern, and
the roughness reduced portion is formed in the region overlapping with the periphery of the bottom surface of the opening on the surface of the pad.
